(19) United States
(12) Patent Application Publication
(10) Pub. No.: US 2022/0416011 A1
(43) Pub. Date: Dec. 29, 2022

(54) CAPACITOR STRUCTURE

(71) Applicant: MediaTek Singapore Pte. Ltd., Singapore (SG)

(72) Inventors: Chang LIANG, Singapore (SG); Zhigang DUAN, Singapore (SG); Kuei-Ti CHAN, Hsinchu City (TW)

(21) Appl. No.: 17/752,003

(22) Filed: May 24, 2022

Related U.S. Application Data
(60) Provisional application No. 63/213,801, filed on Jun. 23, 2021.

(51) Int. Cl. H01L 49/02

(52) U.S. Cl. CPC H01L 28/60

(57) ABSTRACT

Capacitor structures are provided. A capacitor structure includes a first metal line, a second metal line, a plurality of first capacitor cells coupled in parallel between the first metal line and the second metal line, and a plurality of second capacitor cells coupled in parallel between the first metal line and the second metal line. Each of the first capacitor cells includes a first bottom electrode coupled to the first metal line, a first dielectric material over the first bottom electrode, and a first top electrode over the first dielectric material and coupled to the second metal line. Each of the second capacitor cells includes a second bottom electrode coupled to the second metal line, a second dielectric material over the second bottom electrode, and a second top electrode over the second dielectric material and coupled to the first metal line.

### CROSS REFERENCE TO RELATED APPLICATIONS

This application claims priority of U.S. Provisional Application No. 63/213,801, filed on Jun. 23, 2021, the entirety of which is incorporated by reference herein.

### BACKGROUND OF THE INVENTION

### Field of the Invention

The invention relates to a capacitor array, and more particularly to a capacitor array with low equivalent series inductance (ESL).

### Description of the Related Art

Integrated circuits (ICs) have become increasingly important. Applications using ICs are used by millions of people. These applications include cell phones, smartphones, tablets, laptops, notebook computers, PDAs, wireless email terminals, MP3 audio and video players, and portable wireless web browsers. Integrated circuits increasingly include powerful and efficient on-board data storage and logic circuitry for signal control and processing.

As high performance ICs demand more current at higher frequencies with lower power supply voltages, power system design becomes increasingly challenging. It becomes more and more important to use decoupling capacitor to reduce power noise when a digital circuit such as a microprocessor includes numerous transistors that alternate between ON & OFF states.

### BRIEF SUMMARY OF THE INVENTION

Capacitor structures are provided. An embodiment of a capacitor structure is provided. The capacitor structure includes a first metal line, a second metal line, a plurality of first capacitor cells coupled in parallel between the first metal line and the second metal line, and a plurality of second capacitor cells coupled in parallel between the first metal line and the second metal line. Each of the first capacitor cells includes a first bottom electrode coupled to the first metal line, a first dielectric material over the first bottom electrode, and a first top electrode over the first dielectric material and coupled to the second metal line. Each of the second capacitor cells includes a second bottom electrode coupled to the second metal line, a second dielectric material over the second bottom electrode, and a second top electrode over the second dielectric material and coupled to the first metal line.

Furthermore, an embodiment of a capacitor structure is provided. The capacitor structure includes a capacitor array. The capacitor array includes a plurality of first metal lines, a plurality of second metal lines parallel to the first metal lines, a plurality of first capacitor cells arranged in odd columns of the capacitor array, and a plurality of second capacitor cells arranged in even columns of the capacitor array. The first and second metal lines are arranged alternately. First bottom electrodes of the first capacitor cells are coupled to the first metal lines, and first top electrodes of the first capacitor cells are coupled to the second metal lines. Second bottom electrodes of the second capacitor cells are coupled to the second metal lines, and second top electrodes of the second capacitor cells are coupled to the first metal lines. The first voltage applied to the first metal lines is different from the second voltage applied to the second metal lines. Each of the first capacitor cells and each of the second capacitor cells have the same capacitance.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 is a schematic illustrating a capacitor array according to some embodiments of the invention.

FIG. 2 shows the capacitor structure of the area in the capacitor array of FIG. 1 according to some embodiments of the invention.

FIG. 3A shows a cross-sectional view of the capacitor cell along line A-AA in FIG. 2, in accordance with some embodiments of the disclosure.

FIG. 3B shows a cross-sectional view of the capacitor cell along line B-BB in FIG. 2, in accordance with some embodiments of the disclosure.

FIG. 3C shows a cross-sectional view of the capacitor cell along line C-CC in FIG. 2, in accordance with some embodiments of the disclosure.

FIG. 4 shows a cross-sectional view of the capacitor cell in accordance with some embodiments of the disclosure.

FIG. 5 shows a schematic circuit of the row ROW2 in FIG. 2 according to some embodiments of the invention.

FIG. 6 is a schematic illustrating a capacitor array according to some embodiments of the invention.

FIG. 7 shows a capacitor structure of the area in the capacitor array of FIG. 6 according to some embodiments of the invention.

FIG. 8 is a schematic illustrating a capacitor array according to some embodiments of the invention.

FIG. 9 shows the capacitor structure of the area in the capacitor array of FIG. 8 according to some embodiments of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

Some variations of the embodiments are described. Throughout the various views and illustrative embodiments, like reference numbers are used to designate like elements. It should be understood that additional operations can be provided before, during, and/or after a disclosed method, and some of the operations described can be replaced or eliminated for other embodiments of the method.

Furthermore, spatially relative terms, such as “beneath,” “below,” “lower,” “above,” “upper” and the like, may be used herein for ease of description to describe one element or feature's relationship to another element(s) or feature(s) as illustrated in the figures.

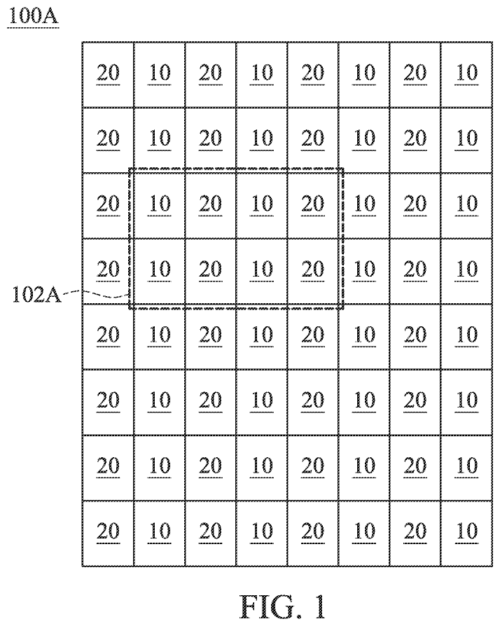

FIG. 1 is a schematic illustrating a capacitor array 100A according to some embodiments of the invention. The capacitor array 100A includes a plurality of capacitor cells 10 and a plurality of capacitor cells 20. In the capacitor array 100A, the capacitor cells 10 and 20 are alternately arranged in each row. Moreover, the columns formed by the capacitor cells 10 and the columns formed by the capacitor cells 20 are alternately arranged. In some embodiments, the capacitor cells 10 are arranged in odd columns and the capacitor cells 20 are arranged in even columns. In some embodiments, the capacitor cells 20 are arranged in odd columns and the capacitor cells 10 are arranged in even columns.

In some embodiments, the capacitor cells 10 and the capacitor cells 20 have the same capacitance. In some embodiments, the capacitor cells 10 and the capacitor cells 20 have the similar structure. For example, the top electrodes of the capacitor cells 10 and 20 are formed in the same upper metal layer (i.e., in the same level), and the bottom electrodes of the capacitor cells 10 and 20 are formed in the same lower metal layer (i.e., in the same level). In addition, the difference between the capacitor cells 10 and the capacitor cells 20 is that the connection configurations of the capacitor cells 10 and 20 are different. For example, each top electrode of the capacitor cells 10 is coupled to a power line (e.g., VDD) through the correspond metal lines, and each top electrode of the capacitor cells 20 is coupled to a ground line (e.g., VSS/GND) through the correspond metal lines. Moreover, each bottom electrode of the capacitor cells 10 is coupled to a ground line through the correspond metal lines, and each top electrode of the capacitor cells 20 is coupled to a power line through the correspond metal lines. The capacitor array 100A functions as a decoupling capacitor between the power line and the ground line.

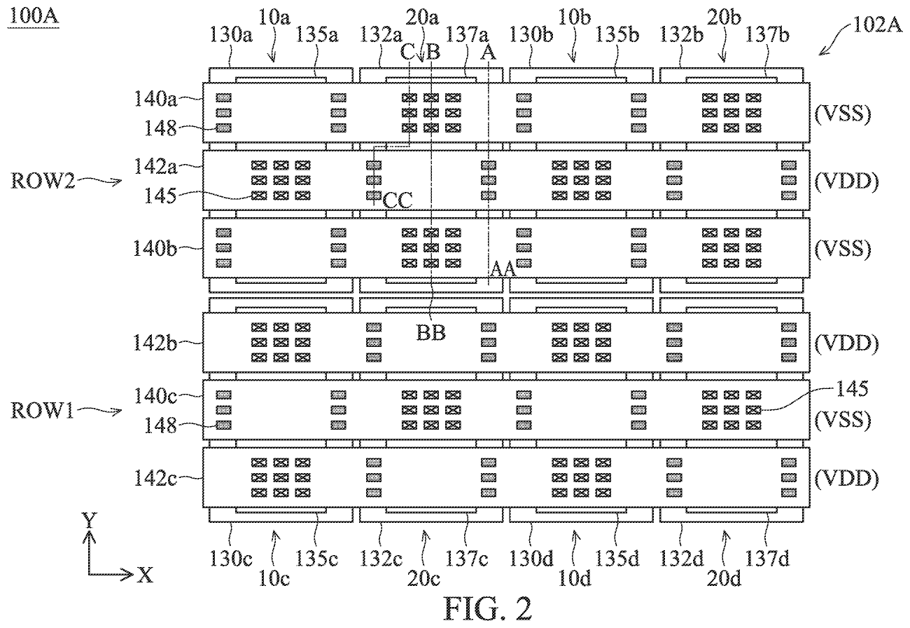

FIG. 2 shows the capacitor structure of the area 102A in the capacitor array 100A of FIG. 1 according to some embodiments of the invention. In the area 102A, the capacitor cells 10a, 20a, 10b and 20b are alternately arranged in the row ROW2. The capacitor cell 10a includes the bottom electrode 130a and the top electrode 135a, wherein the bottom electrode 130a has larger area than the top electrode 135a. The capacitor cell 20a includes the bottom electrode 132a and the top electrode 137a, wherein the bottom electrode 132a has larger area than the top electrode 137a. The capacitor cell 10b includes the bottom electrode 130b and the top electrode 135b, wherein the bottom electrode 130b has larger area than the top electrode 135b. The capacitor cell 20b includes the bottom electrode 132b and the top electrode 137b, wherein the bottom electrode 132b has larger area than the top electrode 137b. Furthermore, the number of capacitor cells 10 is equal to the number of capacitor cells 20 in the capacitor array 100A.

The bottom electrodes of the capacitor cells 10 and 20 have the same area. For example, the bottom electrode 130a of the capacitor cell 10a and the bottom electrode 132a of the capacitor cell 20a have the same area. Moreover, the top electrodes of the capacitor cells 10 and 20 have a first area. For example, the top electrode 135a of the capacitor cell 10a and the top electrode 137a of the capacitor cell 20a have a second area. In some embodiments, the bottom electrode of the capacitor cell 10/20 is coupled to the corresponding signal line through the upper connecting structure, and the first area is greater than the second area. In some embodiments, the bottom electrode of the capacitor cell 10/20 is coupled to the corresponding signal line through the lower connecting structure, and the first area is less than or equal to the second area.

In some embodiments, the bottom electrodes 130a and 130b and the bottom electrodes 132a and 132b are formed in a first metal layer, and the top electrodes 135a and 135b and the top electrodes 137a and 137b are formed in a second metal layer over the first metal layer. In some embodiments, the bottom electrodes 130a, 130b, 132a and 132b have the same area, and the top electrodes 135a, 135b, 137a and 137b have the same area. Furthermore, the bottom electrodes 130a, 130b, 132a and 132b and the top electrodes 135a, 135b, 137a and 137b are formed by the same conductive material, e.g., tungsten (W).

The capacitor cells 10c, 20c, 10d and 20d are alternately arranged in the row ROW 1. Similarly, the bottom electrodes 130c and 130d and the bottom electrodes 132c and 132d are formed in the first metal layer, and the top electrodes 135c and 135d and the top electrodes 137c and 137d are formed in the second metal layer. In some embodiments, the bottom electrodes 130c, 130d, 132c and 132d have the same area, and the top electrodes 135c, 135d, 137c and 137d have the same area that is less than that of the bottom electrodes 130c, 130d, 132c and 132d.

The top electrodes 135a through 135d and 137a through 137d extend in Y-direction. Moreover, the top electrodes arranged in the same column are separated from each other. For example, the top electrode 135a is separated from the top electrode 135c, and the top electrodes 137a is separated from the top electrode 137c.

The bottom electrodes 130a through 130d and 132a through 132d extend in Y-direction. Furthermore, the bottom electrodes arranged in the same column are separated from each other. For example, the bottom electrode 130a is separated from the bottom electrode 130c, and the bottom electrodes 132a is separated from the bottom electrode 132c. In some embodiments, the bottom electrodes arranged in the same column are integrated in the same bottom electrode. In other words, the bottom electrodes arranged in the same column share the same bottom electrode.

In FIG. 2, the metal lines 140a through 140c and the metal lines 142a through 142c are formed in the same metal layer and over the capacitor cells 10a through 10d and 20a through 20d. The metal lines 140a through 140c and 142a through 142c extend in the X-direction and are alternately arranged. For example, the metal line 142a is parallel to and arranged between the metal lines 140a and 140b, and the metal line 140b is parallel to and arranged between the metal lines 142a and 142b. The metal lines 140a through 140c are configured to provide a first voltage signal to the capacitor cells 10 and 20, and the metal lines 142a through 142c are configured to provide a second voltage signal to the capacitor cells 10 and 20, wherein the first voltage signal is different from the second voltage signal. In some embodiments, the metal lines 140a through 140c are the ground lines and the metal lines 142a through 142c are the power lines. In some embodiments, the metal lines 140a through 140c are the power lines and the metal lines 142a through 142c are the ground lines.

In the row ROW2, the metal lines 140a and 140b are coupled to the bottom electrodes 130a and 130b through the vias (contact or the connecting features) 148. Furthermore, the metal lines 140a and 140b are coupled to the top electrodes 137a and 137b through the vias (contact or the connecting features) 145. The metal line 142a is coupled to the bottom electrodes 132a and 132b through the vias 148. Furthermore, the metal line 142a is coupled to the top electrodes 135a and 135b through the vias 145. In the row ROW1, the metal line 140c is coupled to the bottom electrodes 130c and 130d through the vias 148. Furthermore, the metal line 140c is coupled to the top electrodes 137c and 137d through the vias 145. The metal lines 142b and 142c are coupled to the bottom electrodes 132c and 132d through the vias 148. Furthermore, the metal lines 142b and 142c are coupled to the top electrodes 135c and 135d through the vias 145. It should be noted that the number of vias 145 and 148 are used as an example, and not to limit the invention.

As described above, the capacitor cells 10 and 20 have similar structures. The structure of the capacitor cells 10 and 20 will be described below by taking the capacitor cell 20a as an example. Furthermore, it is assumed that the metal lines 140a through 140c are configured to provide the ground signal VSS, and the metal lines 142a through 142c are configured to provide the power signal VDD.

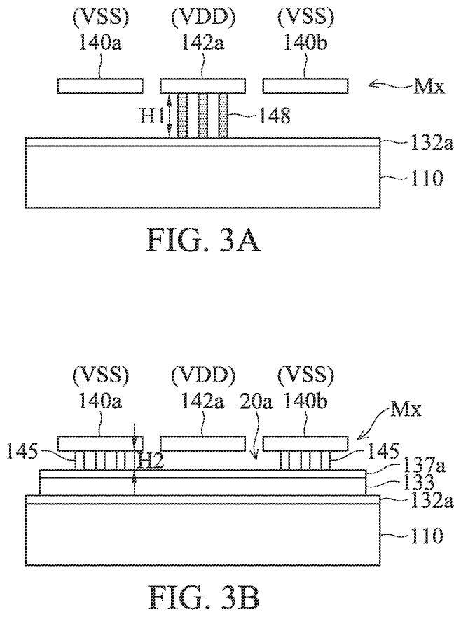

FIG. 3A shows a cross-sectional view of the capacitor cell 20a along line A-AA in FIG. 2, in accordance with some embodiments of the disclosure. The bottom electrode 132a is formed over a semiconductor substrate 110. The metal lines 140a, 142a and 140b are formed in a metal layer Mx over the bottom electrode 132a. The metal line 142a is coupled to the bottom electrode 132a through the vias 148. Thus, the power signal VDD is applied to the bottom electrode 132a through the vias 148 and the metal line 142a. The via 148 has a height (thickness or depth) H1.

FIG. 3B shows a cross-sectional view of the capacitor cell 20a along line B-BB in FIG. 2, in accordance with some embodiments of the disclosure. The bottom electrode 132a is formed over the semiconductor substrate 110. A dielectric material 133 is formed over the bottom electrode 132a. The top electrode 137a is formed over the dielectric material 133. Thus, the capacitor cell 20a is composed of the bottom electrode 132a, the dielectric material 133 and the top electrode 137a. The metal lines 140a, 142a and 140b are formed over the top electrode 137a and in the metal layer Mx. The metal lines 140a and 140b are coupled to the top electrode 137a through the vias 145. Thus, the ground signal VSS is applied to the top electrode 137a through the vias 145 and the metal lines 140a and 140b. The via 145 has a height (or thickness or depth) H2, and the via 145 is shorter than the via 148, i.e., the height H2 is less than the height H1 (H2<H1). In the capacitor array 100A, the dielectric materials of the capacitor cells 10 and 20 are formed by the same dielectric material.

FIG. 3C shows a cross-sectional view of the capacitor cell 20a along line C-CC in FIG. 2, in accordance with some embodiments of the disclosure. The bottom electrode 132a is formed over the semiconductor substrate 110. The dielectric material 133 is formed over the bottom electrode 132a, and the top electrode 137a is formed over the dielectric material 133. The metal line 140a is coupled to the top electrode 137a through the vias 145. Thus, the ground signal VSS is applied to the top electrode 137a through the vias 145 and the metal line 140a. The metal line 142a is coupled to the bottom electrode 132a through the vias 148. Thus, the power signal VDD is applied to the bottom electrode 132a through the vias 148 and the metal line 142a.

In FIGS. 3A through 3C, the capacitor cell 20a is formed over the semiconductor substrate 110, and the bottom electrode 132a is in direct contact with the semiconductor substrate 110. In other words, no other device is formed between the bottom electrode 132a and the semiconductor substrate 110. The respective voltages are applied to the top electrode and the bottom electrode of each capacitor cell through the metal lines over the capacitor cell.

In some embodiments, some devices (e.g., the passive devices or the active devices) are formed over the semiconductor substrate 110, and the capacitor array is formed over the devices. Therefore, the respective voltages are applied to the top electrode and the bottom electrode of a capacitor cell through the metal lines over the capacitor and/or the metal lines under the capacitor.

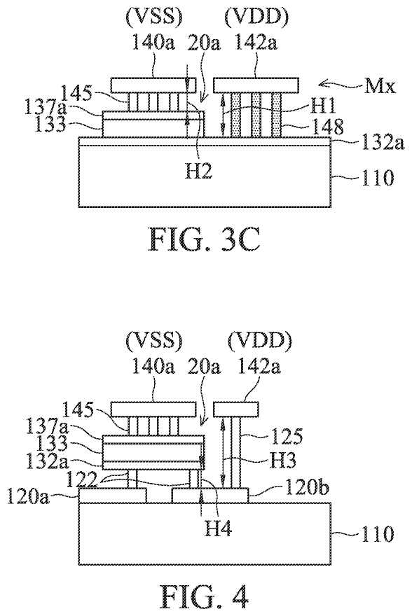

FIG. 4 shows a cross-sectional view of the capacitor cell 20a in accordance with some embodiments of the disclosure. In such embodiment, the capacitor cell 20a is a metal-insulator-metal (MIM) capacitor. The capacitor cell 20a is formed over the devices (e.g., the passive devices, the active devices or the memory cells). In FIG. 4, the power signal VDD is applied to the bottom electrode 132a from the metal line 142a through the via 125, the metal line 120b and the via 122, and from the metal line 120a through the via 122. In some embodiments, the metal lines 120a and 120b are formed in the lowest metal layer. Furthermore, the via 125 has a height (or thickness or depth) H3, and the via 125 is longer than the via 148, i.e., the height H1 is less than the height H3 (H1<H3). Moreover, the via 122 has a height (or thickness or depth) H4, and the via 122 is shorter than the via 148, i.e., the height H4 is less than the height H1 (H4<H1). In some embodiments, the vias 122 and 145 have the same height, i.e., the height H4 is equal to the height H2 (H4═H2).

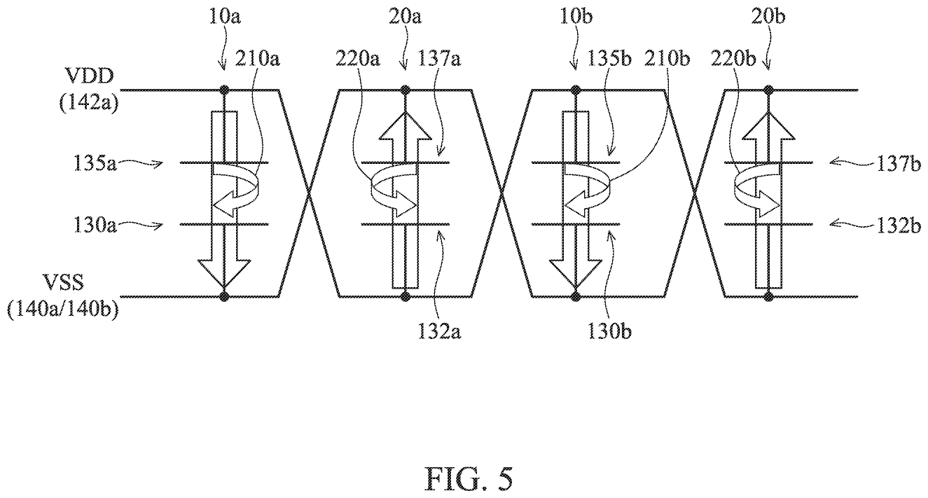

FIG. 5 shows a schematic circuit of the row ROW2 in FIG. 2 according to some embodiments of the invention. Referring to FIG. 2 and FIG. 5 together, the capacitor cells 10a, 20a, 10b and 20b are coupled in parallel between the metal line 142a (VDD) and the metal line 140a/140b (i.e., VSS). The capacitor cell 10a is coupled to the metal line 142a through the top electrode 135a. Moreover, the capacitor cell 20a is further coupled to the metal line 142a (VDD) through the bottom electrode 132a. Furthermore, the capacitor cell 10b is further coupled to the metal line 142a (VDD) through the top electrode 135b. Moreover, the capacitor cell 20b is further coupled to the metal line 142a (VDD) through the bottom electrode 132b. The capacitor cell 10a is coupled to the metal line 140a/140b (VSS) through the bottom electrode 130a. Moreover, the capacitor cell 20a is further coupled to the metal line 140a/140b (VSS) through the top electrode 137a. Furthermore, the capacitor cell 10b is further coupled to the metal line 140a/140b (VSS) through the bottom electrode 130b. Moreover, the capacitor cell 20b is further coupled to the metal line 140a/140b (VSS) through the top electrode 137b.

The capacitor cells 10a and 10b are separated by the capacitor cell 20a, i.e., the capacitor cell 20a is disposed between the capacitor cells 10a and 10b. The capacitor cells 20a and 20b are separated by the capacitor cell 10b, i.e., the capacitor cell 10b is disposed between the capacitor cells 20a and 20b. In the same row, the capacitor cells 10 and 20 are arranged to overlap the corresponding metal line. For example, the capacitor cells 10a, 20a, 10b and 20b overlap the metal lines 140a, 142a and 140b. Moreover, the capacitor cells 10a and 10b and the capacitor cells 20a and 20b are alternately arranged under the metal lines 140a, 142a and 140b.

In the capacitor cell 10a, a magnetic field 210a is formed since the current flows from the top electrode 135a to the bottom electrode 130a. In the capacitor cell 20a, a magnetic field 220a is formed since the current flows from the bottom electrode 132a to the top electrode 137a. In the capacitor cell 10c, a magnetic field 210b is formed since the current flows from the top electrode 135b to the bottom electrode 130b. In the capacitor cell 20b, a magnetic field 220b is formed since the current flows from the bottom electrode 132b to the top electrode 137b.

In FIG. 5, the magnetic fields 210a and 210b and the magnetic fields 220a and 220b may have inductive cancellation because the charges on the top electrode and the bottom electrode of the capacitor cells 10 and the charges on the top electrode and the bottom electrode of the capacitor cells 20 are moving in opposite directions, thereby allowing the magnetic fields 210a and 210b and the magnetic fields 220a and 220b to cancel rather than reinforce each other.

Compared with the traditional capacitor cells that have all top electrode coupled to the power signal VDD and all bottom electrode coupled to the ground signal VSS, when the capacitor cells in the capacitor array 100A increase, the equivalent series inductance (ESL) will not increase. In some embodiments, the capacitor array 100A may function as a decoupling capacitor to reduce power noise caused by digital circuits including numerous transistors that alternate between ON and OFF states.

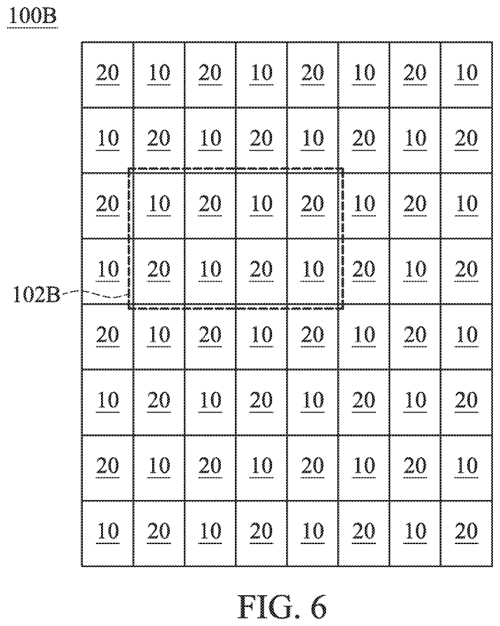

FIG. 6 is a schematic illustrating a capacitor array 100B according to some embodiments of the invention. The capacitor array 100B includes a plurality of capacitor cells 10 and a plurality of capacitor cells 20. Compared with the capacitor array 100A of FIG. 1, the capacitor cells 10 and 20 are alternately arranged in each row and each column in the capacitor array 100B. Therefore, each capacitor cell 10 is surrounded by the capacitor cells 20, and each capacitor cell 20 is surrounded by the capacitor cells 10 in the capacitor array 100B. Furthermore, the number of capacitor cells 10 is equal to the number of capacitor cells 20 in the capacitor array 100B.

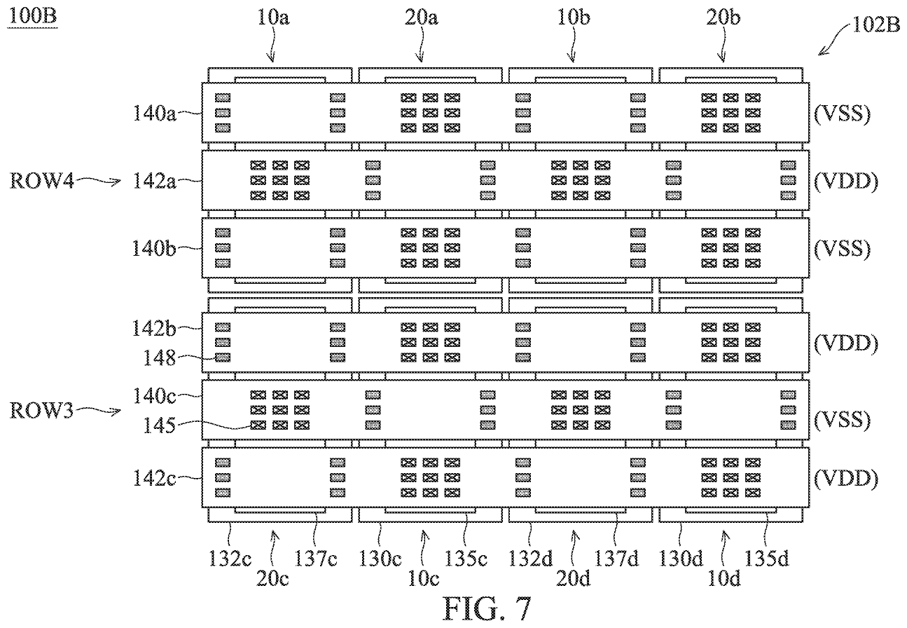

FIG. 7 shows a capacitor structure of the area 102B in the capacitor array 100B of FIG. 6 according to some embodiments of the invention. In the area 102B, the capacitor cells 10a, 20a, 10b and 20b are alternately arranged in the upper row. Furthermore, the connection configurations between the capacitor cells 10a, 20a, 10b and 20b and the metal lines 140a, 142a and 140b in the row ROW4 are similar to the related configuration in the row ROW2 of FIG. 2.

In FIG. 7, the capacitor cells 20c, 10c, 20d and 10d are alternately arranged in the row ROW3. The capacitor cell 20c and the capacitor cell 10a are arranged in the same column, and the capacitor cell 10c and the capacitor cell 20a are arranged in the same column. Moreover, the capacitor cell 20d and the capacitor cell 10b are arranged in the same column, and the capacitor cell 10d and the capacitor cell 20b are arranged in the same column.

Similar to FIG. 2, the metal lines 140a through 140c and the metal lines 142a through 142c are formed over the capacitor cells 10a through 10d and 20a through 20d. The metal lines 140a through 140c and 142a through 142c extend in the X-direction and are alternately arranged. Moreover, it is assumed that the metal lines 140a through 140c are configured to provide the ground signal VSS, and the metal lines 142a through 142c are configured to provide the power signal VDD. It should be noted that the bottom electrodes arranged in the same column are separated from each.

In the row ROW3, the metal line 140c is coupled to the bottom electrodes 130c and 130d through the vias 148, and the metal line 140c is coupled to the top electrodes 137c and 137d through the vias 145. The metal lines 142b and 142c are coupled to the bottom electrodes 132c and 132d through the vias 148, and the metal lines 142b and 142c are coupled to the top electrodes 135c and 135d through the vias 145. Therefore, by arranging the order of the power lines and the ground lines and arranging the arrangement of the vias 145 and 148, the capacitor cells 10 and capacitor cells 20 can be arranged in the capacitor array (e.g., 100A or 100B) in any known way.

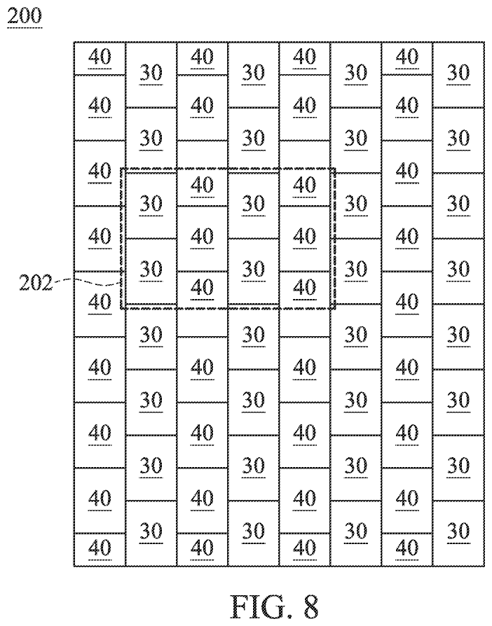

FIG. 8 is a schematic illustrating a capacitor array 200 according to some embodiments of the invention. The capacitor array 200 includes a plurality of capacitor cells 30 and a plurality of capacitor cells 40. In the capacitor array 200, the columns formed by the capacitor cells 30 and the columns formed by the capacitor cells 40 are alternately arranged. In some embodiments, the capacitor cells 30 are arranged in odd columns and the capacitor cells 40 are arranged in even columns. In some embodiments, the capacitor cells 40 are arranged in odd columns and the capacitor cells 30 are arranged in even columns. In some embodiments, the capacitor cells 30 and the capacitor cells 40 have the same capacitance. In some embodiments, the capacitor cells 30 and the capacitor cells 40 have the similar structure. For example, each top electrode of the capacitor cells 30 and 40 are formed in the same upper metal layer, and each bottom electrode of the capacitor cells 30 and 40 are formed in the same lower metal layer. In addition, the difference between the capacitor cells 30 and the capacitor cells 40 is that the connection configurations of the capacitor cells 30 and 40 are different. For example, each top electrode of the capacitor cells 30 is coupled to a power line (e.g., VDD) through the correspond metal lines, and each top electrode of the capacitor cells 40 is coupled to a ground line (e.g., VSS/GND) through the correspond metal lines. Moreover, each bottom electrode of the capacitor cells 30 is coupled to a ground line through the correspond metal lines, and each top electrode of the capacitor cells 40 is coupled to a power line through the correspond metal lines. Furthermore, the number of capacitor cells 30 is equal to the number of capacitor cells 40 in the capacitor array 200.

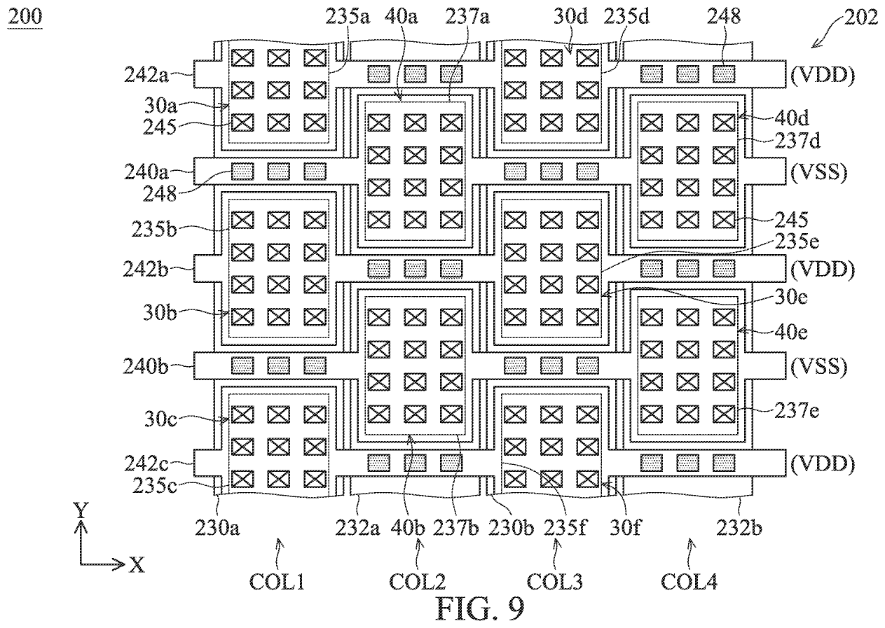

FIG. 9 shows the capacitor structure of the area 202 in the capacitor array 200 of FIG. 8 according to some embodiments of the invention. In the area 202, the capacitor cells 30a, 30b and 30c are arranged in the column COL1. The capacitor cell 30a is composed of the bottom electrode 230a, the top electrode 235a (marked with a dashed line) and the dielectric material (not shown) between the electrodes 230a and 235a. In such embodiment, the top electrode of each capacitor cell 30/40 is marked with a dashed line. The top electrode 235a is coupled to the metal line 242a through the vias (contact or the connecting features) 245. The capacitor cell 30b is composed of the bottom electrode 230a, the top electrode 235b and the dielectric material (not shown). The top electrode 235b is coupled to the metal line 242b through the vias 245. Moreover, the capacitor cell 30c is composed of the bottom electrode 230a, the top electrode 235c and the dielectric material (not shown). The top electrode 235c is coupled to the metal line 242c through the vias 245. It should be noted that the capacitor cells 30a, 30b and 30c share the bottom electrode 230a. The bottom electrode 230a is coupled to the metal lines 240a and 240b through the vias 248. In such embodiment, the metal lines 242a through 242c are configured to provide the power signal VDD, and the metal lines 240a and 240b are configured to provide the ground signal VS S. Moreover, the via 245 is shorter than the via 248.

The capacitor cells 40a and 40b are arranged in the column COL2. The capacitor cell 40a is composed of the bottom electrode 232a, the top electrode 237a and the dielectric material (not shown) between the electrodes 232a and 237a. The top electrode 237a is coupled to the metal line 240a through the vias 245. The capacitor cell 40b is composed of the bottom electrode 232a, the top electrode 237b and the dielectric material (not shown). The top electrode 237b is coupled to the metal line 240b through the vias 245. Similarly, the capacitor cells 40a and 40b arranged in the same column share the same bottom electrode 232a. The bottom electrode 232a is coupled to the metal lines 242a, 242b and 242c through the vias 248. Furthermore, the dielectric material of the capacitor cells 30 and 40 are formed by the same dielectric material.

The capacitor cells 30d, 30e and 30f are arranged in the column COL3. The capacitor cell 30d is composed of the bottom electrode 230b, the top electrode 235d and the dielectric material (not shown) between the electrodes 230b and 235d. The top electrode 235d is coupled to the metal line 242a through the vias 245. The capacitor cell 30e is composed of the bottom electrode 230b, the top electrode 235e and the dielectric material (not shown). The top electrode 235e is coupled to the metal line 242b through the vias 245. The capacitor cell 30f is composed of the bottom electrode 230b, the top electrode 235f and the dielectric material (not shown). The top electrode 23fe is coupled to the metal line 242c through the vias 245. Similarly, the capacitor cells 30d, 30e and 30f arranged in the same column share the same bottom electrode 230b. The bottom electrode 230b is coupled to the metal lines 240a and 240b through the vias 248.

The capacitor cells 40d and 40e are arranged in the column COL4. The capacitor cell 40d is composed of the bottom electrode 232b, the top electrode 237d and the dielectric material (not shown) between the electrodes 232b and 237d. The top electrode 237d is coupled to the metal line 240a through the vias 245. The capacitor cell 40e is composed of the bottom electrode 232b, the top electrode 237e and the dielectric material (not shown). The top electrode 237e is coupled to the metal line 240b through the vias 245. Similarly, the capacitor cells 40d and 40e arranged in the same column share the same bottom electrode 232b. The bottom electrode 232b is coupled to the metal lines 242a, 242b and 242c through the vias 248.

The top electrodes of the capacitor cells 30 and 40 have the same area. For example, the top electrode 235b of the capacitor cell 30b and the top electrode 237a of the capacitor cell 40a have the same area. Furthermore, the bottom electrodes of the capacitor cells 30 and 40 have the greater area than the top electrodes of the capacitor cells 30 and 40. For example, the area of the bottom electrode 230a is greater than that of the top electrodes 235a, 235b and 235c.

Compared with the capacitor array 100A of FIG. 2 and the capacitor array 100B of FIG. 7 that the metal lines 140a through 140c and the metal lines 142a through 142c have a fixed width, the metal lines 240a and 240b and the metal lines 242a through 242c in the capacitor array 200 have multiple widths. For example, the metal lines 240a and 240b have a width W1 in the columns COL1 and COL3 and a width W2 in the columns COL2 and COL4, and the width W1 is less than the width W2 (i.e., W1<W2). The width W2 is large enough to completely cover the upper electrodes 237a, 237b, 237d and 237e of the capacitor cells 40a, 40b, 40d and 40e. Similarly, the metal lines 242a through 242c have the narrower width (e.g., the width W1) in the columns COL2 and COL4 and the wider width (e.g., the width W2) in the columns COL1 and COL3.

Taking the metal line 242a (VDD) and the metal line 240a (VS S) as an illustration, the capacitor cells 30a, 40a, 30d and 40d are coupled in parallel between the power line (i.e., the metal line 242a) and the ground line (i.e., the metal line 240a). The capacitor cells 30a and 30d are separated by the capacitor cell 40a, and the capacitor cells 40a and 40d are separated by the capacitor cell 30d. The magnetic fields of the capacitor cell 30a and 30d are opposite to the magnetic fields of the capacitor cell 40a and 40d, thereby causing inductive cancellation. Compared with the capacitor array 100A of FIG. 2 and the capacitor array 100B of FIG. 7 that the top electrodes in the capacitor cells 10 and 20 are coupled to the corresponding metal lines through the different amounts of vias 145, the top electrodes in the capacitor cells 30 and 40 are coupled to the corresponding metal lines through the same amount of vias 245. For example, the top electrode 135a of the capacitor cell 10a is coupled to the metal line 142a through nine vias 145, and the top electrode 135c of the capacitor cell 10c is coupled to the metal lines 142b and 142c through eighteen vias 145, thereby the arrangement of vias 145 are unbalance in the capacitor arrays 100A and 100B. In the capacitor array 200, each top electrode of the capacitor cells 30 and 40 is coupled to the corresponding metal line through twelve vias 245, thereby the arrangement of vias 245 is balanced in order to better match the induction elimination.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A capacitor structure, comprising:
a first metal line;
a second metal line;
a plurality of first capacitor cells coupled in parallel between the first metal line and the second metal line, wherein each of the first capacitor cells comprises:
a first bottom electrode coupled to the first metal line;
a first dielectric material over the first bottom electrode; and
a first top electrode over the first dielectric material and coupled to the second metal line; and
a plurality of second capacitor cells coupled in parallel between the first metal line and the second metal line, wherein each of the second capacitor cells comprises:
a second bottom electrode coupled to the second metal line;
a second dielectric material over the second bottom electrode; and
a second top electrode over the second dielectric material and coupled to the first metal line.

2. The capacitor structure as claimed in claim 1, wherein two adjacent first capacitor cells are separated by one of the second capacitor cells, and two adjacent second capacitor cells are separated by one of the first capacitor cells.

3. The capacitor structure as claimed in claim 1, wherein the first bottom electrodes of the first capacitor cells and the second bottom electrodes of the second capacitor cells are formed in the same level, and the first top electrodes of the first capacitor cells and the second top electrodes of the second capacitor cells are formed in the same level.

4. The capacitor structure as claimed in claim 1, wherein the first and second metal lines are formed in the same metal layer over the first and second capacitor cells.

5. The capacitor structure as claimed in claim 4, wherein the first bottom electrode of each of the first capacitor cells is coupled to the first metal line through a plurality of first connecting features, and the first top electrode of each of the first capacitor cells is coupled to the second metal line through a plurality of second connecting features, wherein a first height of the first connecting feature is greater than a second height of the second connecting feature.

6. The capacitor structure as claimed in claim 5, wherein the second bottom electrode of each of the second capacitor cells is coupled to the second metal line through the second connecting features, and the second top electrode of each of the second capacitor cells is coupled to the first metal line through the first connecting features.

7. The capacitor structure as claimed in claim 1, wherein the first capacitor cells and the second capacitor cells overlap the first and second metal lines, and the first capacitor cells and the second capacitor cells are alternately arranged under the first and second metal lines.

8. The capacitor structure as claimed in claim 1, wherein each of the first capacitor cells and each of the second capacitor cells have the same capacitance, and the number of first capacitor cells is equal to the number of second capacitor cells.

9. The capacitor structure as claimed in claim 1, wherein the first and second bottom electrodes have the same first area, and the first and second top electrodes have the same second area, wherein the first area is greater than the second area.

10. The capacitor structure as claimed in claim 9, wherein the first area is greater than the second area.

11. A capacitor structure, comprising:
a capacitor array, comprising:
a plurality of first metal lines;
a plurality of second metal lines parallel to the first metal lines, wherein the first and second metal lines are arranged alternately;
a plurality of first capacitor cells arranged in odd columns of the capacitor array; and
a plurality of second capacitor cells arranged in even columns of the capacitor array,
wherein first bottom electrodes of the first capacitor cells are coupled to the first metal lines, and first top electrodes of the first capacitor cells are coupled to the second metal lines,
wherein second bottom electrodes of the second capacitor cells are coupled to the second metal lines, and second top electrodes of the second capacitor cells are coupled to the first metal lines,
wherein a first voltage applied to the first metal lines is different from a second voltage applied to the second metal lines.

12. The capacitor structure as claimed in claim 11, wherein in each row of the capacitor array, the first capacitor cells of two adjacent columns are separated by one of the second capacitor cells, and the second capacitor cells of two adjacent columns are separated by one of the first capacitor cells.

13. The capacitor structure as claimed in claim 11, wherein the first bottom electrodes of the first capacitor cells and the second bottom electrodes of the second capacitor cells are formed in the same level, and the first top electrodes of the first capacitor cells and the second top electrodes of the second capacitor cells are formed in the same level.

14. The capacitor structure as claimed in claim 11, wherein the number of first capacitor cells is equal to the number of second capacitor cells, and each of the first capacitor cells and each of the second capacitor cells have the same capacitance.

15. The capacitor structure as claimed in claim 14, wherein the first bottom electrode of each of the first capacitor cells is coupled to the first metal line through a plurality of first connecting features, and the first top electrode of each of the first capacitor cells is coupled to the second metal line through a plurality of second connecting features, wherein a first height of the first connecting feature is greater than a second height of the second connecting feature.

16. The capacitor structure as claimed in claim 15, wherein the second bottom electrode of each of the second capacitor cells is coupled to the second metal line through the second connecting features, and the second top electrode of each of the second capacitor cells is coupled to the first metal line through the first connecting features.

17. The capacitor structure as claimed in claim 11, wherein the first capacitor cells arranged in the same column share the same first bottom electrode, and the second capacitor cells arranged in the same column share the same second bottom electrode.

18. The capacitor structure as claimed in claim 11, wherein the first and second bottom electrodes have the same first area, and the first and second top electrodes have the same second area, wherein the first area is greater than the second area.

19. The capacitor structure as claimed in claim 11, wherein the first and second metal lines have a fixed width.

20. The capacitor structure as claimed in claim 11, wherein the first and second metal lines have different widths in odd columns and even columns of the capacitor array.
